(19) United States
(12) Patent Application Publication
(10) Pub. No.: US 2025/0085803 A1
(43) Pub. Date: Mar. 13, 2025

(54) BASE PLATE PREFORM, DISPLAY MODULE PREFORM AND METHODS FOR MANUFACTURING BASE PLATE PREFORM AND DISPLAY MODULE PREFORM

(71) Applicants: Hefei Visionox Technology Co., Ltd., Hefei (CN); KunShan Go-Visionox Opto-Electronics Co., Ltd., Kunshan (CN)

(72) Inventors: Yao LI, Hefei (CN); Wenzhi FAN, Hefei (CN); Fei CHEN, Hefei (CN); Haifeng PENG, Hefei (CN); Linqing LIU, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/954,480

(22) Filed: Nov. 20, 2024

(30) Foreign Application Priority Data
Dec. 29, 2023 (CN) 202311872624.8

(51) Int. Cl. G06F 3/041; H10K 59/38; H10K 59/40; H10K 59/80

(52) U.S. Cl. CPC G06F 3/04164; G06F 3/0412; H10K 59/38; H10K 59/40; H10K 59/879; G06F 2203/04103

(57) ABSTRACT

Embodiments of the present application provides a base plate preform, a display module preform and methods for manufacturing them, the base plate preform comprising a functional area and a bonding area, the base plate preform further comprising: a substrate; a metal layer located on a side of the substrate, the metal layer comprising a metal wiring located in the functional area and a bonding pad located in the bonding area; a first organic layer located on a side of the metal layer away from the substrate, the first organic layer covering the metal wiring and at least a sidewall of the bonding pad.

### CROSS-REFERENCE TO RELATED APPLICATION

The present application claims priority to Chinese Patent Application No. 202311872624.8 filed on Dec. 29, 2023, and titled “BASE PLATE PREFORM, DISPLAY MODULE PREFORM AND METHODS FOR MANUFACTURING BASE PLATE PREFORM AND DISPLAY MODULE PREFORM”, which is incorporated herein by reference in its entirety.

### TECHNICAL FIELD

The present application relates to the technical field of display, and particularly relates to a base plate preform, a display module preform and methods for manufacturing them.

### BACKGROUND

With the development of display technology, requirements for display devices become higher, and in current display devices, the performance of a bonding pad for realizing electrical connection of a chip and a circuit in the display device needs to be improved.

### SUMMARY

Embodiments of the present application provide a base plate preform, a display module preform and methods for manufacturing them, which can improve the protection effect to a bonding pad, thereby improving the yield of product.

Embodiments of a first aspect of the present application provides a base plate preform, comprising a functional area and a bonding area, the base plate preform further comprising:
a substrate;
a metal layer located on a side of the substrate, the metal layer comprising a metal wiring located in the functional area and a bonding pad located in the bonding area;
a first organic layer located on a side of the metal layer away from the substrate, the first organic layer covering the metal wiring and at least a sidewall of the bonding pad.

In embodiments of the first aspect of the present application, the first organic layer covers the metal wiring and the bonding pad;
preferably, the first organic layer covers the functional area and the bonding area;
preferably, a thickness of the first organic layer in the functional area is greater than or equal to a thickness of the first organic layer in the bonding area;
preferably, the first organic layer comprises an organic adhesive;
preferably, the first organic layer comprises an acrylic adhesive layer, a silica gel layer, a polyurethane adhesive layer, an ultraviolet curing adhesive layer, a polyimide adhesive layer or a photoresist layer;
preferably, the bonding pad comprises at least two metal layers stacked;
preferably, the bonding pad comprises a first titanium metal layer, an aluminum metal layer and a second titanium metal layer that are stacked.

In embodiments of the first aspect of the present application, the metal layer is a touch metal layer comprising a first metal layer, and the first organic layer is provided on a side of the first metal layer away from the substrate;
preferably, the touch metal layer further comprises a second metal layer located on a side of the first metal layer away from the substrate, the first metal layer comprising the bonding pad located in the bonding area;
preferably, the first organic layer is located between the first metal layer and the second metal layer, or the first organic layer is located on a side of the second metal layer away from the substrate;
preferably, the touch metal layer further comprises a second metal layer located on a side of the first metal layer away from the substrate, the first metal layer or the second metal layer comprising the bonding pad located in the bonding area, and the first organic layer is located on a side of the second metal layer away from the substrate;
preferably, the first metal layer comprises a touch lead located in the bonding area, the touch lead being electrically connected with the bonding pad;
preferably, the metal layer is an array metal layer, and the first organic layer is a planarization layer.

Embodiments of a second aspect of the present application provides a display module preform, comprising the base plate preform of the first aspect.

In embodiments of the second aspect of the present application, further comprising an optical improvement layer located on a side of the first organic layer away from the substrate;
preferably, the optical improvement layer comprises a second organic layer, an orthographic projection of the second organic layer on the substrate not overlapping with an orthographic projection of the bonding pad on the substrate;
preferably, the second organic layer covers the functional area;
preferably, the second organic layer comprises an organic adhesive;
preferably, the second organic layer comprises an acrylic adhesive layer, a silica gel layer, a polyurethane adhesive layer, an ultraviolet curing adhesive layer, a polyimide adhesive layer or a photoresist layer;
preferably, the second organic layer is made of a same material as the first organic layer;
preferably, the optical improvement layer comprises at least one of a color filter layer and a microlens layer;
preferably, the display module preform further comprises a light-emitting layer comprising a plurality of light-emitting units, and the optical improvement layer comprises a color filter layer, the second organic layer being located on a side of the color filter layer away from the substrate, the color filter layer comprising a light shielding layer and color filter portions, orthographic projections of the color filter portions on the substrate at least partially overlapping with orthographic projections of the light-emitting units on the substrate, and the light shielding layer being located between the color filter portions;

or, the optical improvement layer comprises a microlens layer comprising a first optical functional layer and a second optical functional layer that are stacked, a refractive index of the first optical functional layer being different from a refractive index of the second optical functional layer, and the second organic layer being located on a side of the microlens layer away from the substrate.

Embodiments of a third aspect of the present application provides a display module, comprising a display area and a bonding area, the display module further comprising a base plate comprising a substrate, a metal layer and a third organic layer, the metal layer being provided with a bonding pad in the bonding area, the third organic layer covering the display area, and an orthographic projection of the third organic layer on the substrate not overlapping with an orthographic projection of the bonding pad on the substrate.

In embodiments of the third aspect of the present application, the base plate is a touch base plate, the metal layer is a touch metal layer comprising a first metal layer, the third organic layer being provided on a side of the first metal layer away from the substrate;
preferably, the touch metal layer further comprises a second metal layer located on a side of the first metal layer away from the substrate, the first metal layer or the second metal layer comprising the bonding pad located in the bonding area;
preferably, the third organic layer is located between the first metal layer and the second metal layer, or the third organic layer is located on a side of the second metal layer away from the substrate;
preferably, the touch metal layer further comprises a second metal layer located on a side of the first metal layer away from the substrate, the second metal layer comprising the bonding pad located in the bonding area, and the third organic layer being located on a side of the second metal layer away from the substrate;
preferably, the first metal layer comprises a touch lead located in the bonding area and electrically connected with the bonding pad;
preferably, the base plate is an array base plate, the metal layer is an array metal layer, and the third organic layer is a planarization layer.

In embodiments of the third aspect of the present application, the bonding pad comprises at least two metal layers stacked;
preferably, the bonding pad comprises a first titanium metal layer, an aluminum metal layer and a second titanium metal layer that are stacked.

In embodiments of the third aspect of the present application, further comprising an optical improvement layer provided on a side of the third organic layer away from the substrate, wherein the optical improvement layer comprises a fourth organic layer, an orthographic projection of the fourth organic layer on the display panel not overlapping with an orthographic projection of the bonding pad on the display panel;
preferably, the fourth organic layer covers the display area;
preferably, the optical improvement layer comprises at least one of a color filter layer and a microlens layer;
preferably, the display module further comprises a light-emitting layer comprising a plurality of light-emitting units, the optical improvement layer comprising a color filter layer, the second organic layer being located on a side of the color filter layer away from the substrate, the color filter layer comprising a light shielding layer and color filter portions, orthographic projections of the color filter portions on the substrate at least partially overlap with orthographic projections of the light-emitting units on the substrate, and the light shielding layer being located between the color filter portions;
or, the optical improvement layer comprises a microlens layer comprising a first optical functional layer and a second optical functional layer that are stacked, a refractive index of the first optical functional layer being different from a refractive index of the second optical functional layer, and the second organic layer being located on a side of the microlens layer away from the substrate.

In embodiments of the third aspect of the present application, no other film layer is provided in a same layer as the bonding pad in the bonding area;
preferably, the third organic layer and the fourth organic layer comprise an organic adhesive;
preferably, the third organic layer and the fourth organic layer comprise an acrylic adhesive layer, a silica gel layer, a polyurethane adhesive layer, an ultraviolet curing adhesive layer, a polyimide adhesive layer or a photoresist layer.

Embodiments of a fourth aspect of the present application provides a method for manufacturing a base plate preform, the base plate preform comprising a bonding area and a functional area, the method comprising:
providing a substrate;
forming a metal layer on a side of the substrate, the metal layer comprising a metal wiring located in the functional area and a bonding pad located in the bonding area;
forming a first organic layer on a side of the metal layer away from the substrate, the first organic layer covering the metal wiring and at least a sidewall of the bonding pad;
preferably, the first organic layer is formed on a side of the metal layer away from the substrate, and the first organic layer covers the functional area and the bonding area.

In embodiments of the fourth aspect of the present application, the step of forming a first organic layer on a side of the metal layer away from the substrate, the first organic layer covering the functional area and the bonding area comprises:
forming the first organic layer with a thickness in the functional area greater than or equal to a thickness in the bonding area;
preferably, forming the first organic layer with a thickness in the functional area greater than or equal to a thickness in the bonding area comprises:
providing a mask plate on a side of the first organic layer away from the display panel, the mask comprising a non-light-transmitting area and a semi-light-transmitting area, the non-light-transmitting area being provided corresponding to the functional area, and the semi-light-transmitting area being provided corresponding to the bonding area;
illuminating a side of the mask plate away from the first organic layer;
developing an area of the semi-light-transmitting area corresponding to the base plate by a developing solution, to make a thickness of the first organic layer located in the functional area is greater than a thickness of the first organic layer located in the bonding area;
preferably, the semi-light-transmitting area comprises a light-shielding film layer, or the semi-light-transmitting area comprises a plurality of strip-shaped through holes penetrating through the mask plate in a thickness direction, a distance between adjacent strip-shaped through holes being 1 μm-2 μm;
preferably, the first organic layer comprises an acrylic adhesive layer, a silica gel layer, a polyurethane adhesive layer, an ultraviolet curing adhesive layer, a polyimide adhesive layer or a photoresist layer.

Embodiments of a fourth aspect of the present application provides a method for manufacturing a display module, comprising:
providing a base plate preform, which is the base plate preform of the first aspect or manufactured by the method provided by the fourth aspect;
forming an optical improvement layer on a side of the first organic layer away from the substrate, the optical improvement layer comprising a second organic layer formed on a side of the first organic layer away from the substrate, and an orthographic projection of the second organic layer on the substrate not overlapping with an orthographic projection of the bonding pad on the substrate;
thinning the first organic layer located in the bonding area and the second organic layer to thin the second organic layer and form a fourth organic layer, and to remove a part of the first organic layer located in the bonding area to form a third organic layer, to make the third organic layer covers the functional area;
preferably, the step of forming the second organic layer on a side of the first organic layer away from the substrate comprises: covering the functional area with the second organic layer;
preferably, the step of thinning the first organic layer located in the bonding area and the second organic layer comprises: ashing the first organic layer located in the bonding area and the second organic layer.

Embodiments of a fifth aspect of the present application provides a display device, comprising the display module of the second aspect; or comprising the display module manufactured by the method of the fifth aspect.

The base plate preform provided by the application comprises a functional area and a bonding area, and further comprises a substrate, a metal layer and a first organic layer. The metal layer is located on a side of the substrate and comprises a metal wire and a bonding pad, the metal wire is used for realizing signal transmission to realize a corresponding function, and the bonding pad is used for bonding with the chip. The first organic layer is located on a side of the metal layer away from the substrate, the first organic layer covers the metal wiring to protect and insulate the metal wiring, and the first organic layer further covers at least a side wall of the bonding pad to protect the bonding pad, specifically, protect the material in the bonding pad, thus damage to the bonding pad caused by the subsequent process is improved, the damage to the bonding pad caused by the subsequent process may specifically comprise the problem that the bonding pad is error side etched due to corrosion of the material in the bonding pad by the etching solution in the subsequent process. In addition, the first organic layer can further completely cover the bonding pad, so that the protection effect on the bonding pad can be further improved, and the yield of the product can be improved.

### BRIEF DESCRIPTION OF THE DRAWINGS

In order to more clearly describe the technical solutions of the embodiments of the present application, the following briefly describes the accompanying drawings that need to be used in the embodiments of the present application, and obviously, the accompanying drawings described below are merely some embodiments of the present application, for those skilled in the art, other drawings can also be obtained according to these drawings without creative labor.

FIG. 1 is a top view of a base plate preform provided in an embodiment of the present application;

FIG. 2 is a sectional view along M-M′ in FIG. 1;

FIG. 3 is a sectional view along M-M′ in FIG. 1;

FIG. 4 is a sectional view along M-M′ in FIG. 1;

FIG. 5 is a sectional view along M-M′ in FIG. 1;

FIG. 6 is a sectional view along M-M′ in FIG. 1;

FIG. 7 is a cross-sectional view of a base plate preform provided in another embodiment of the present application;

FIG. 8 is a schematic structural diagram of a display module preform provided in an embodiment of the present application;

FIG. 9 is a schematic structural diagram of a display module preform provided in another embodiment of the present application;

FIG. 10 is a schematic structural diagram of a display module preform provided in another embodiment of the present application;

FIG. 11 is a schematic structural diagram of a display module preform provided in another embodiment of the present application;

FIG. 12 is a schematic structural diagram of a display module preform provided in another embodiment of the present application;

FIG. 13 is a schematic structural diagram of a display module provided in an embodiment of the present application;

FIG. 14 is a schematic structural diagram of a display module provided in an embodiment of the present application;

FIG. 15 is a schematic structural diagram of a display module provided in an embodiment of the present application;

FIG. 16 is a schematic structural diagram of a display module provided in an embodiment of the present application;

FIG. 17 is a schematic structural diagram of a display module provided in an embodiment of the present application;

FIG. 18 is a schematic structural diagram of a display module provided in an embodiment of the present application;

FIG. 19 is a schematic structural diagram of a display module provided in an embodiment of the present application;

FIG. 20 is a flowchart of a method for manufacturing a base plate preform provided in an embodiment of the present application;

FIG. 21 is a schematic diagram of a method for manufacturing a base plate preform provided in an embodiment of the present application;

FIG. 22 is a schematic diagram of a method for manufacturing a base plate preform provided in an embodiment of the present application.

FIG. 23 is a schematic diagram of a method for manufacturing a base plate preform provided in an embodiment of the present application;

FIG. 24 is a flowchart of a method for manufacturing a display module provided in an embodiment of the present application; and

FIG. 25 is a schematic structural diagram of a display device provided in an embodiment of the present application.

In the drawings:
1: base plate preform; A1: functional area; B: bonding area; 11: substrate; 12: metal layer; 120: metal wiring; 121: bonding pad; 122: first metal layer; 1221: touch lead; 123: second metal layer; 124: first conductive layer; 125: second conductive layer; 126: third conductive layer; 127: fourth conductive layer; 128: fifth conductive layer; 13: first organic layer; 14: insulating layer; 2: display module preform; 21: display panel; 210: light-emitting unit; 211: first electrode; 212: light-emitting functional layer; 213: second electrode; 22: optical improvement layer; 221: second organic layer; 222: color filter layer; 2221: light shielding layer; 2222: color filter part; 223: microlens layer; 2231: first optical functional layer; 2232: second optical functional layer; A2: display area; 3: touch panel; 31: third organic layer; 220: fourth organic layer; 4: display device; 5: mask plate; 51: non-light-transmitting area; 52: semi-light-transmitting area; 521: strip-shaped through hole; 6: display module.

### DETAILED DESCRIPTION

Features and exemplary embodiments of various aspects of the present application are described in detail below. In the following detailed description, numerous specific details are set forth in order to provide a thorough understanding of the present application. However, it will be apparent to those skilled in the art that the present application may be practiced without some of these specific details. The following description of the embodiments is merely intended to provide a better understanding of the present application by illustrating examples of the present application.

It should be noted that, in this specification, relational terms such as first and second are merely used to distinguish one entity or operation from another entity or operation, and do not necessarily require or imply that there is any such actual relationship or order between these entities or operations. Moreover, the terms “comprises”, “comprising” or any other variant thereof are intended to cover a non-exclusive inclusion, such that a process, method, article or device comprising a series of elements comprises not only those elements, but also other elements not explicitly listed, or elements inherent to such process, method, article or device. Without more limitations, elements defined by the statement “comprising” do not preclude the presence of additional identical elements in a process, method, article, or device that comprises the elements.

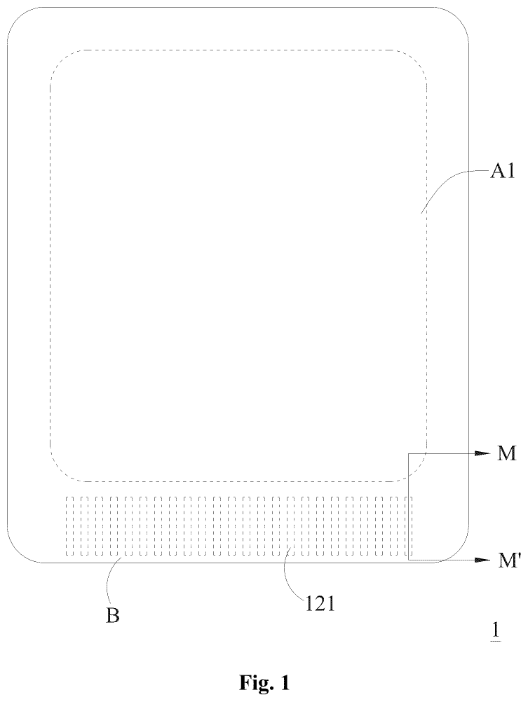

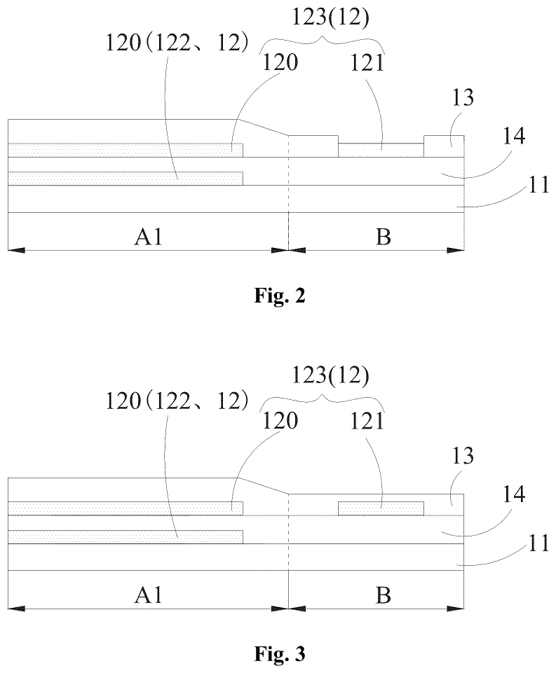

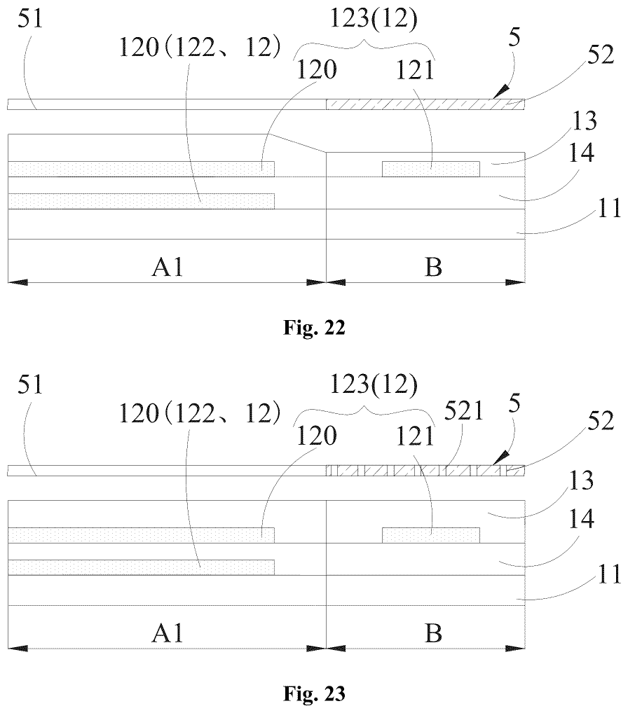

In order to better understand the present application, in combination with embodiments of FIG. 1 to FIG. 25, the following describes a touch panel preform, a display module preform, a display module and a display device, and also methods for manufacturing a touch panel preform and a display module in detail.

Referring to FIG. 1 to FIG. 3, embodiments of the present application provide a base plate preform 1, comprising a functional area A1 and a bonding area B, and also a substrate 11, a metal layer 12, and a first organic layer 13. The metal layer 12 is located on a side of the substrate 11 and comprises a metal wiring 120 located in the functional area A1 and a bonding pad 121 located in the bonding area B. The first organic layer 13 is located on a side of the metal layer 12 away from the substrate 11 and covers the metal wiring 120 and at least a sidewall of the bonding pad 121.

The base plate preform 1 provided by the present application comprises a functional area A1 and a bonding area B, and also a substrate 11, a metal layer 12 and a first organic layer 13. The metal layer 12 is located on a side of the substrate 11 and comprises a metal wiring 120 and a bonding pad 121, the metal wiring 120 is configured to transmit signal to implement a corresponding function, and the bonding pad 121 is configured to be bonded with a chip. The first organic layer 13 is located on a side of the metal layer 12 away from the substrate 11 and covers the metal wiring 120 to protect and insulate the metal wiring 120. The first organic layer 13 further covers at least a side wall of the bonding pad 121 to protect the bonding pad 121. Specifically, a material in the bonding pad 121 can be protected to avoid the damage caused by subsequent processes, the damage being the bonding pad 121 error side etched due to the corrosion of the subsequent process etching solution on the bonding pad 121. In addition, the first organic layer 13 may further completely cover the bonding pad 121, thereby further improving the protection effect on the bonding pad 121 and the yield of the product.

In an embodiment, as shown in FIG. 3, the first organic layer 13 covers the metal wiring 120 and the bonding pad 121.

In the above embodiment, when the first organic layer 13 completely covers the bonding pad 121, the first organic layer 13 can be synchronously removed after protecting the bonding pad 121 in some subsequent processes, so that one removal process can be reduced, thereby simplifying the manufacturing process, improving the production efficiency and reducing the cost.

In an embodiment, as shown in FIG. 3, the first organic layer 13 covers the functional area A1 and the bonding area B.

In the above embodiment, the first organic layer 13 may be manufactured as a whole surface, so that the first organic layer 13 covers the functional area A1 and the bonding area B, the manufacturing process is simplified and the first organic layer 13 is well insulated and protected.

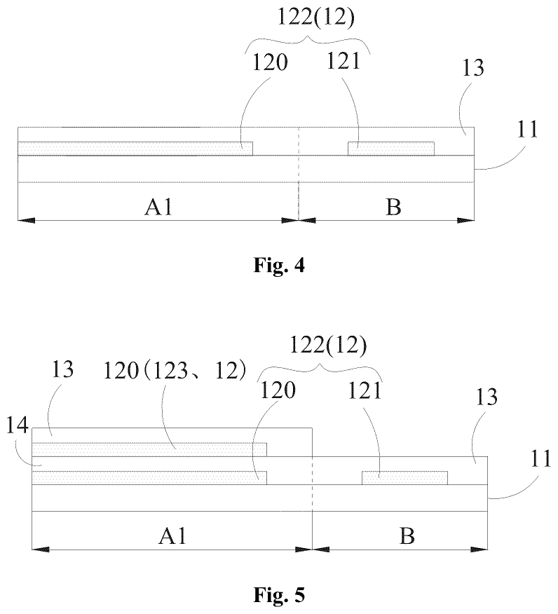

In an embodiment, as shown in FIG. 3 and FIG. 4, a thickness of the first organic layer 13 located in the functional area A1 is greater than or equal to a thickness of the first organic layer 13 located in the bonding area B.

Specifically, the thickness of the first organic layer 13 located in the functional area A1 may be equal to the thickness of the first organic layer 13 located in the bonding area B, so that the first organic layer 13 can be manufactured as a whole layer rather than in a partitioned manner, thereby simplifying the manufacturing process and reducing the manufacturing cost.

Specifically, the thickness of the first organic layer 13 located in the functional area A1 is greater than the thickness of the first organic layer 13 located in the bonding area B. That is, the part of the first organic layer 13 located in the functional area A1 is thicker, so that the metal wiring 120 is well protected and insulated, and protection failure and insulation failure caused by exposing the metal wiring 120 are prevented. The part of the first organic layer 13 located in the bonding area B is thinner, so that the part of the first organic layer 13 located in the bonding area B can be removed synchronously in the subsequent manufacturing process, that is the first organic layer 13 is removed after protecting the bonding pad 121. That is, the bonding pad 121 can be protected by the first organic layer 13, and after that, the first organic layer 13 is removed synchronically by the subsequent process to expose the bonding pad 121, so as to achieve the electrical connection of bonding pad 121 and reduce the process of removing the first organic layer 13, simplifying the process and save costs.

In an embodiment, the first organic layer 13 comprises an organic adhesive facilitated the bending of the base plate preform 1, thus the base plate preform 1 can be applied to a flexible product, such as a flexible display module, in the application process, thereby ensuring the bending performance of the product and effectively avoiding the problem of film separation in the bending process.

In the above embodiment, the organic adhesive is used for simplifying the process of removing the first organic layer 13, and can be simultaneously removed in a subsequent process, so as to expose the bonding pad 121 and facilitate subsequent bonding.

In an embodiment, the first organic layer 13 comprises an acrylic adhesive layer, a silica gel layer, a polyurethane adhesive layer, an ultraviolet curing adhesive layer, a polyimide adhesive layer or a photoresist layer, which are easy to obtain and low in cost; other organic adhesives may also be used, which is not particularly limited in the present application.

In an embodiment, the bonding pad 121 comprises at least two metal layers (not shown in the figure) stacked; specifically, one of the two metal layers away from the substrate 11 may have a relatively strong corrosion resistance, thereby protecting the other metal layer.

In a possible embodiment, the bonding pad 121 comprises a first titanium metal layer, an aluminum metal layer, and a second titanium metal layer that are stacked.

In the above embodiment, the aluminum metal layer is easily corroded by the etching solution, thus the first organic layer 13 covers an edge of the bonding pad 121, specifically covers an edge of the aluminum metal layer to protect the aluminum metal layer from being corroded.

In a possible embodiment, as shown in FIG. 4, the base plate preform may be a touch base plate preform, and the functional area may be a touch area. The metal layer 12 is a touch metal layer comprising a first metal layer 122, and the first organic layer 13 is provided on a side of the first metal layer 122 away from the substrate 11.

In the above embodiment, the first metal layer 122 comprises a metal wiring 120 located in the functional area A1, that is, located in the touch area. The first metal layer 122 may further comprise a bonding pad 121 located in the bonding area B. That is, the first metal layer 122 and the bonding pad 121 are made of a same material and formed by a same process.

In the foregoing embodiment, the first organic layer 13 is provided on a side of the first metal layer 122 away from the substrate 11, and is configured to insulate and protect the metal wiring 120, and can also be configured to protect the bonding pad 121.

In an embodiment, as shown in FIG. 5, the touch metal layer further comprises a second metal layer 123 located on a side of the first metal layer 122 away from the substrate 11; and the first metal layer 122 comprises a bonding pad 121 located in the bonding area B.

In the above embodiment, the metal layer 12 may further comprise a second metal layer 123 comprising a metal wiring 120 located in the functional area A1, that is, located in the touch area. When the bonding pad 121 is formed on the first metal layer 122, an orthographic projection of the second metal layer 123 on the substrate 11 does not overlap with an orthographic projection of the bonding pad 121 on the substrate 11. Specifically, the orthographic projection of the second metal layer 123 on the substrate 11 does not overlap with an orthographic projection of the bonding area B on the substrate 11.

In the above embodiment, the first organic layer 13 is located between the first metal layer 122 and the second metal layer 123. The insulation between the first metal layer 122 and the second metal layer 123 can be realized, while the bonding pad 121 located in the bonding area B in the first metal layer 122 can be protected.

Alternatively, as shown in FIG. 5, the first organic layer 13 is located on a side of the second metal layer 123 away from the substrate 11; and a part of the first organic layer 13 located in the bonding area B at least covers a peripheral side of the bonding pad 121. In this case, an insulating layer 14 may be further provided between the first metal layer 122 and the second metal layer 123, that is, between the part of the first metal layer 122 located in the functional area A1 and the part of the second metal layer 123 located in the functional area A1.

Specifically, the insulating layer 14 is made of an inorganic material, such as silicon nitride and silicon oxide. Or the insulating layer 14 is made of an organic material, such as an organic adhesive, specifically, the insulating layer 14 may comprise an acrylic adhesive layer, a silica gel layer, a polyurethane adhesive layer, an ultraviolet curing adhesive layer, a polyimide adhesive layer, or a photoresist layer.

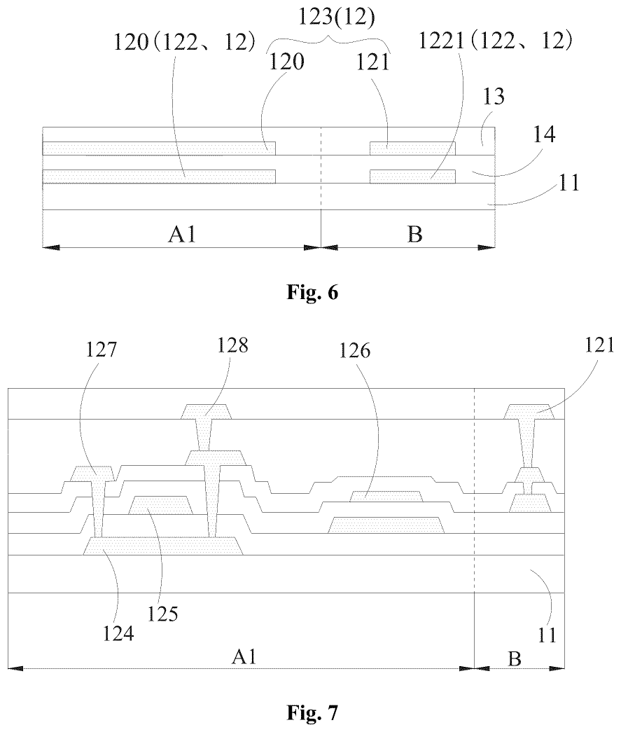

In another embodiment, as shown in FIG. 6, the touch metal layer further comprises a second metal layer 123 located on a side of the first metal layer 122 away from the substrate 11; the second metal layer 123 comprises a bonding pad 121 located in the bonding area B; and the first organic layer 13 is located on a side of the second metal layer 123 away from the substrate 11. In the above embodiment, the bonding pad 121 is located on the second metal layer 123, and may also form a metal wiring located in the functional area A1, that is, the metal wiring and the bonding pad 121 are formed synchronously; the first organic layer 13 is located on a side of the second metal layer 123 away from the substrate 11, so that the first organic layer 13 can protect and insulate the second metal layer 123, and also can protect the bonding pad 121, thereby improving the side etching problem of the bonding pad 121.

In the above embodiment, the first metal layer 122 comprises a touch lead 1221 located in the bonding area B and electrically connected with the bonding pad 121.

In the foregoing embodiment, an insulating layer 14 may be further provided between the first metal layer 122 and the second metal layer 123, a material of which may comprise at least one of an organic material or an inorganic material, and the insulating layer 14 is configured to implement insulation between the first metal layer 122 and the second metal layer 123.

It should be noted that the metal layer 12 in the above embodiment comprises a first metal layer 122 and a second metal layer 123, the metal layer 12 being a touch metal layer, that is, the base plate preform 1 is a touch base plate preform; the first metal layer 122 and the second metal layer 123 serve as touch wiring layers, for example, the first metal layer 122 serves as a bridge point electrode layer, and the second metal layer 123 serves as a touch electrode layer.

In an embodiment, the metal layer 12 is an array metal layer, that is, the base plate preform 1 is an array base plate preform, and the first organic layer 13 is a planarization layer provided on a side of the array metal layer away from the substrate 11.

Specifically, referring to FIG. 7, the array metal layer may comprise a first conductive layer 124, a second conductive layer 125, a third conductive layer 126, and a fourth conductive layer 127 that are stacked in a direction away from the substrate, and may further comprise a fifth conductive layer 128, no special limit is made in the present application, but only the array metal layer shown in FIG. 7 is used as an example for explanation. In which, the first conductive layer 124 is configured to form a source and drain area and a channel area of a transistor; specifically, the first conductive layer 124 may be a semiconductor layer; and the second conductive layer 125, the third conductive layer 126, the fourth conductive layer 127, and the fifth conductive layer 128 may be made of metals. The metal layer 12 may be any one of the second conductive layer 125, the third conductive layer 126, the fourth conductive layer 127, or the fifth conductive layer 128, for ease of manufacturing; preferably, the metal layer 12 may be the fifth conductive layer 128 comprising the bonding pad 121 located in the bonding area B, that is, the bonding pad 121 located in the bonding area B is synchronously manufactured with the fifth conductive layer 128.

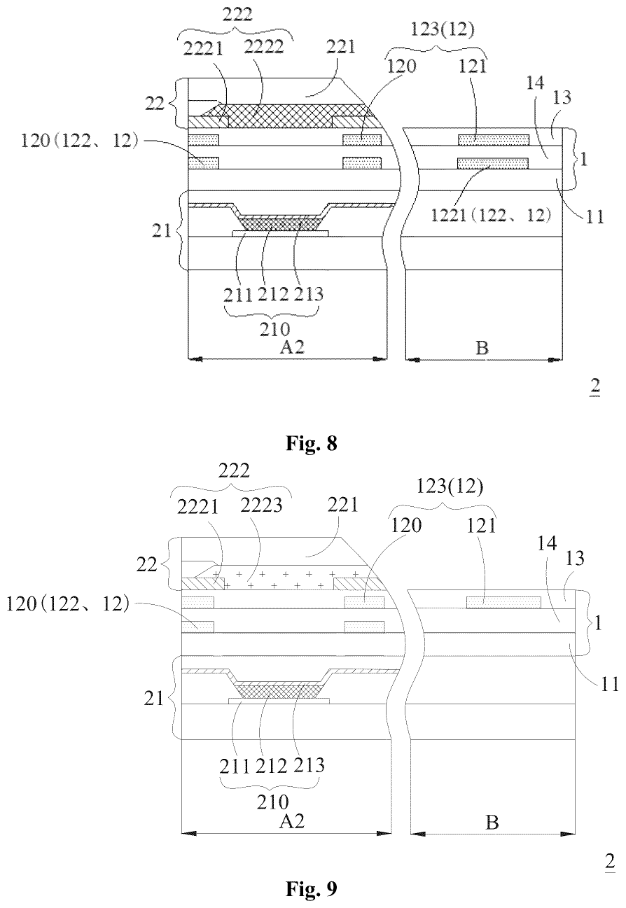

Specifically, the fourth conductive layer 127 and the fifth conductive layer 128 comprise a first titanium metal layer, an aluminum metal layer, and a second titanium metal layer that are stacked. The present application further provides a display module preform 2, as shown in FIG. 8, comprising any one of the base plate preforms 1 provided in the above embodiments. The display module preform 2 comprises the base plate preform 1 provided by the present application, so that the bonding pad 121 can be protected by the first organic layer 13, damage to the bonding pad 121 caused by the process after the manufacturing process of the base plate preform 1 in the manufacturing process of the display module preform 2 can be reduced, and specifically, the problem that the bonding pad 121 is error side etched due to corrosion of the material in the bonding pad 121 by the etching solution in the subsequent process can be reduced.

In an embodiment, as shown in FIG. 8, taking an example that the base plate preform 1 is a touch base plate preform, the display module preform 2 further comprises an optical improvement layer 22 located on a side of the first organic layer 13 away from the substrate 11.

Specifically, it may comprise a display area A2 and a bonding area B surrounding at least part of the display area A2, wherein the functional area A1 corresponds to the display area A2 along a direction perpendicular to the substrate 11, that is, orthographic projections of the functional area A1 and the display area A2 on the substrate 11 overlap.

In the above embodiment, the display module preform 2 further comprises a display panel 21; the substrate preform 1 is located on a light-emitting side of the display panel 21, the optical improvement layer 22 is located on a side of the substrate preform 1 away from the display panel 21 and is configured to improve light emitted by the display panel 21 to improve the light-emitting effect.

In an embodiment, as shown in FIG. 8, the optical improvement layer 22 comprises a second organic layer 221, an orthographic projection of the second organic layer 221 on the substrate 11 does not overlap with an orthographic projection of the bonding pad 121 on the substrate 11.

In the above embodiment, the optical improvement layer 22 comprises a second organic layer 221 located on a side of the optical improvement layer 22 away from the display panel 21 for protection.

Specifically, the orthographic projection of the optical improvement layer 22 on the substrate 11 does not overlap with the orthographic projection of the bonding pad 121 on the substrate 11, thereby preventing the optical improvement layer 22 from blocking the bonding pad 121.

Specifically, the orthographic projection of the second organic layer 221 on the substrate 11 does not overlap with the orthographic projection of the bonding pad 121 on the substrate 11, so that the problem that the film layer above the bonding pad 121 is not easily removed in a same process due to the second organic layer 221 covering the bonding area B is avoided.

In the above embodiment, the second organic layer 221 covers the display area A2, that is, the second organic layer 221 covers the functional area A1 to protect the functional area A1, thus the problem that the film layer above the bonding pad 121 is not easily removed in a same process due to the second organic layer 221 covering the bonding area B is avoided.

In the above embodiment, the second organic layer 221 comprises an organic adhesive; the second organic layer 221 can facilitate subsequent roughening of the second organic layer 221 by using the organic adhesive, and can facilitate removal of the part of the first organic layer 13 located in the bonding area B during roughening of the second organic layer 221.

Specifically, in a direction perpendicular to the substrate 11, a thickness of the second organic layer 221 is greater than a thickness of the first organic layer 13 located in the bonding area B, so that after the part of the first organic layer 13 located in the bonding area B is removed, part of the second organic layer 221 remains to protect the underlying film layer.

Specifically, the second organic layer 221 comprises an acrylic adhesive layer, a silica gel layer, a polyurethane adhesive layer, an ultraviolet curing adhesive layer, a polyimide adhesive layer or a photoresist; the above organic adhesive material is easy to obtain and low in cost; other organic adhesives may also be used, which is not particularly limited in the present application.

In a preferred embodiment, the first organic layer 13 and the second organic layer 221 are made of a same material, so that the first organic layer 13 and the second organic layer 221 can be subsequently processed in a same process.

In the above embodiments, referring to FIG. 8 to FIG. 12, the optical improvement layer 22 comprises at least one of a color filter layer 222 and a microlens layer 223, so as to adjust the light emitted by the display panel 21, thereby achieving a better display effect.

In the above embodiment, the display panel 21 comprises a light-emitting layer comprising a plurality of light-emitting units 210, and the optical improvement layer 22 comprises a color filter layer 222; the second organic layer 221 is located on a side of the color filter layer 222 away from the substrate 11 and protect the color filter layer 222.

Specifically, the light-emitting unit 210 may comprise a first electrode 211, a light-emitting functional layer 212 and a second electrode 213.

In an embodiment, as shown in FIG. 8, the color filter layer 222 comprises a light shielding layer 2221 and color filter portions 2222, orthographic projections of the color filter portions 2222 on the substrate 11 at least partially overlap with orthographic projections of the light-emitting units 210 on the substrate 11, and the light shielding layer 2221 is located between the color filter portions 2222.

In the above embodiment, the color filter portions 2222 may correspond to the color of the light-emitting unit 210, and the color filter portion 2222 may filter the light emitted by the light-emitting unit 210 to improve the purity of the light emitted, and reduce the incident rate of the external light entering the display panel 21, thereby reducing the reflectivity of the display panel 21 to the light incident into the display panel 21.

In the above embodiment, the light shielding layer 2221 can prevent crosstalk and absorb external light incident into the display module to reduce reflection. The light shielding layer 2221 is made of a material capable of absorbing light, specifically, the light shielding layer 2221 may be black and may comprise a black colorant. Black colorant may comprise a black dye or black pigment, such as carbon black and the like.

In another possible embodiment, as shown in FIG. 9, the color filter layer 222 comprises a light shielding layer 2221 and a reflection control layer 2223, the reflection control layer 2223 selectively absorbing light of a specific wavelength band among light reflected from the inside of the display module or light incident from the outside of the display module. For example, the reflection control layer 2223 may absorb light in a first wavelength band of about 490 nm to about 505 nm and a second wavelength band of about 585 nm to about 600 nm, so that the transmittance of the light in the first wavelength band and the second wavelength band is reduced. The reflection control layer 2223 may absorb light of wavelengths outside wavelength ranges of red light, green light, and blue light respectively emitted from the light-emitting unit 210. Since the reflection control layer 2223 absorbs light of wavelengths not belonging to the wavelength range of the red light, the green light, and the blue light emitted from the display panel 21, the problem of brightness reduction of the display module can be improved. In addition, a reduction in light-emitting efficiency of the display module can be prevented or minimized, and visibility of the display module can be improved.

The reflection control layer 2223 may comprise an organic material layer comprising at least one of a dye or a pigment. The reflection control layer 2223 may comprise at least one of a tetraazaporphyrin (TAP) based compound, a porphyrin based compound, a metalloporphyrin based compound, an oxazinyl compound, a squartyl compound, a triarylmethane based compound, a polymethynyl compound, an anthraquinone based compound, a phthalocyanine based compound, an azo based compound, a perylene-based compound, a xanthene based compound, a diimine based compound, a dipyrromethylene based compound, or a cyaninyl compound.

In an embodiment, the reflection control layer 2223 may have a transmittance of about 64% to about 72%. The transmittance of the reflection control layer 2223 may be controlled according to the amount of pigment and/or dye comprised in the reflection control layer 2223.

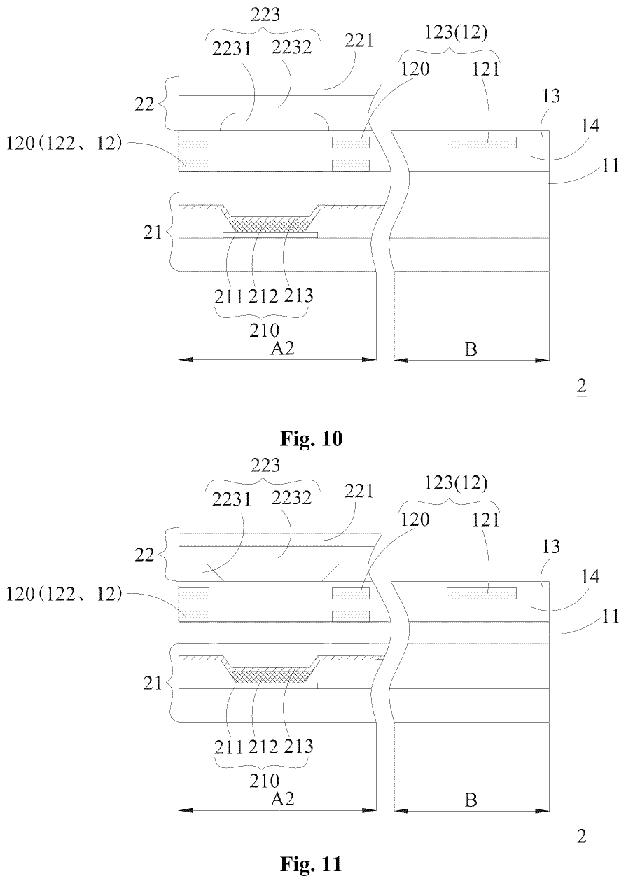

And/or, as shown in FIG. 10, the optical improvement layer 22 comprises a microlens layer 223 comprising a first optical functional layer 2231 and a second optical functional layer 2232 that are stacked, a refractive index of the first optical functional layer 2231 is different from that of the second optical functional layer 2232, and the second organic layer 221 is located on a side of the microlens layer 223 away from the substrate 11.

In the foregoing embodiment, the second optical functional layer 2232 is located on a side of the first optical functional layer 2231 away from the display panel 21, the refractive index of the second optical functional layer 2232 is less than that of the first optical functional layer 2231, the first optical functional layer 2231 may comprise a plurality of pattern parts opposite to the light-emitting units 210, the pattern parts comprising middle parts and edge parts surrounding the middle parts, and a thickness of the edge part tends to decrease along a direction from the middle part to the edge part; therefore, when light (oblique light emitted by the light-emitting unit 210) passes through the first optical functional layer 2231 with a higher refractive index and is incident into the second optical functional layer 2232, the oblique light is refracted, so that the oblique light is converted into light more toward a positive viewing angle, that is, the light is closer to a center, thereby achieving an effect of converging the light, and further improving display brightness of the display module.

Specifically, the display module further comprises an encapsulation layer located between the optical improvement layer 22 and the display panel 21.

In the above embodiment, as shown in FIG. 11, the refractive index of the second optical functional layer 2232 is greater than that of the first optical functional layer 2231, the first optical functional layer 2231 may comprise a plurality of pattern parts staggered with the light-emitting units 210, that is, the pattern parts are located between adjacent light-emitting units 210. The pattern parts comprise middle parts and edge parts surrounding the middle parts, a thickness of the edge part tends to decrease along the direction from the middle part to the edge part; therefore, when the light (the light emitted by the light-emitting unit 210 from the inclined light through the upper film layer) passes through the second optical functional layer 2232 with a higher refractive index and is incident into the first optical functional layer 2231 with a lower refractive index, the light is totally reflected, so that the oblique light is converted into light more toward a positive viewing angle, that is, the light is closer to a center, thereby achieving an effect of converging the light, and further improving display brightness of the display module.

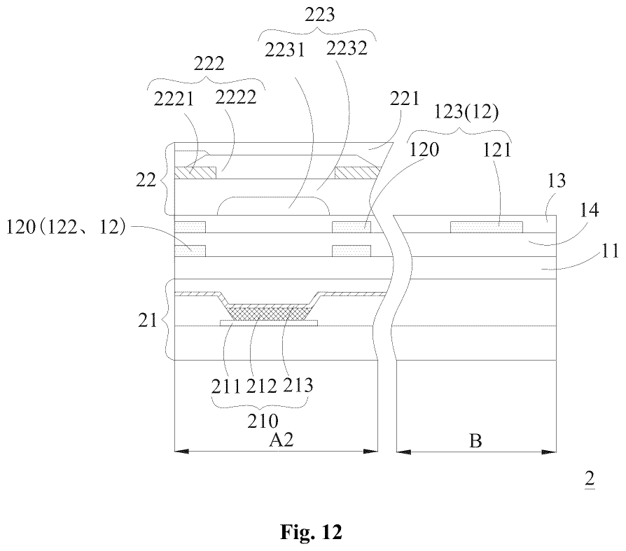

In an embodiment, as shown in FIG. 12, the optical improvement layer 22 comprises a color filter layer 222 and a microlens layer 223, where the color filter layer 222 is located on a side of the microlens layer 223 away from the display panel 21. The second organic layer 221 is located on a side of the optical improvement layer 22 away from the display panel 21 for protecting the optical improvement layer 22.

In an embodiment, the base plate preform 1 is an array base plate preform, a specific structural design of which refers to a related specific structural design of the base plate preform 1, and details are not described herein again.

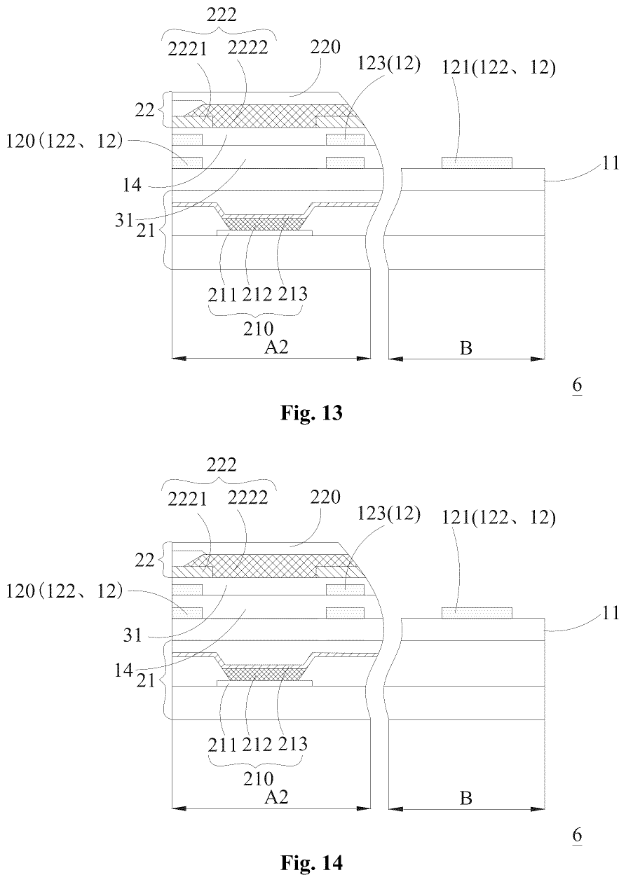

The present application further provides a display module 6, as shown in FIG. 13, comprising a display area A2 and a bonding area B, the bonding area B being provided with a bonding pad 121; the display module further comprises a base plate comprising a substrate 11, a metal layer 12 and a third organic layer 31 which are stacked, the third organic layer 31 covering the display area A2, and an orthographic projection of the third organic layer 31 on the substrate 11 does not overlap with an orthographic projection of the bonding pad 121 on the substrate 11.

In the above embodiment, the display area A2 of the display module 6 corresponds to the functional area A1 of the base plate.

In the above embodiment, the base plate comprises a substrate 11, a metal layer 12 and a third organic layer 31 that are stacked, and specifically, the third organic layer 31 may be obtained by thinning the first organic layer 13, such as removing a part of the first organic layer 13 located in the bonding area B to obtain the third organic layer 31 located in the display area A2 or ashing. That is, the base plate is obtained by processing the base plate preform 1.

In the above embodiment, the display module 6 may further comprise an optical improvement layer 22 provided on a side of the third organic layer 31 away from the substrate 11 and comprising a fourth organic layer 220, an orthographic projection of the fourth organic layer 220 on the substrate 11 does not overlap with an orthographic projection of the bonding pad 121 on the substrate 11.

The optical improvement layer 22 comprises a fourth organic layer 220, which is obtained by thinning the second organic layer 221. For example, ashing is used, which further increase the surface roughness of the fourth organic layer 220 away from the substrate 11, so that the reflectivity of the fourth organic layer 220 is lower than that of the second organic layer 221, thereby improving the visual effect of the display module.

Specifically, the fourth organic layer 220 covers the display area A2 to protect the optical improvement layer 22.

In one embodiment, as shown in FIG. 13, taking an example that the base plate is a touch base plate, the metal layer 12 is a touch metal layer comprising a first metal layer 122; the third organic layer 31 is provided on a side of the first metal layer 122 away from the substrate 11.

In the above embodiment, the third organic layer 31 may protect a part of the first metal layer 122 located in the display area A2, specifically, the first metal layer 122 may comprise a metal wiring 120 located in the display area A2, and the third organic layer 31 may protect the metal wiring 120.

In an embodiment, as shown in FIG. 13, the touch metal layer further comprises a second metal layer 123 located on a side of the first metal layer 122 away from the substrate 11; the first metal layer 122 comprises a bonding pad 121 located in the bonding area B.

In the above embodiment, the metal layer 12 may further comprise a second metal layer 123 comprising a metal wiring 120 located in the display area A2. The bonding pad 121 is formed on the first metal layer 122, the orthographic projection of the second metal layer 123 on the substrate 11 does not overlap with the orthographic projection of the bonding pad 121 on the substrate 11. Specifically, the orthographic projection of the second metal layer 123 on the substrate 11 may not overlap with the orthographic projection of the bonding area B on the substrate 11.

In the above embodiment, as shown in FIG. 13, the third organic layer 31 may be located between the first metal layer 122 and the second metal layer 123, which realizes the insulation between the first metal layer 122 and the second metal layer 123. In this case, an insulating layer 14 may be provided on a side of the second metal layer 123 away from the display panel to insulate and protect the second metal layer 123, and the insulating layer 14 may comprise at least one of an inorganic material and an organic material.

Alternatively, as shown in FIG. 14, the third organic layer 31 is located on a side of the second metal layer 123 away from the substrate 11. In this case, an insulating layer 14 may be further provided between the first metal layer 122 and the second metal layer 123, that is, between the part of the first metal layer 122 located in the functional area A1 and the part of the second metal layer 123 located in the functional area A1.

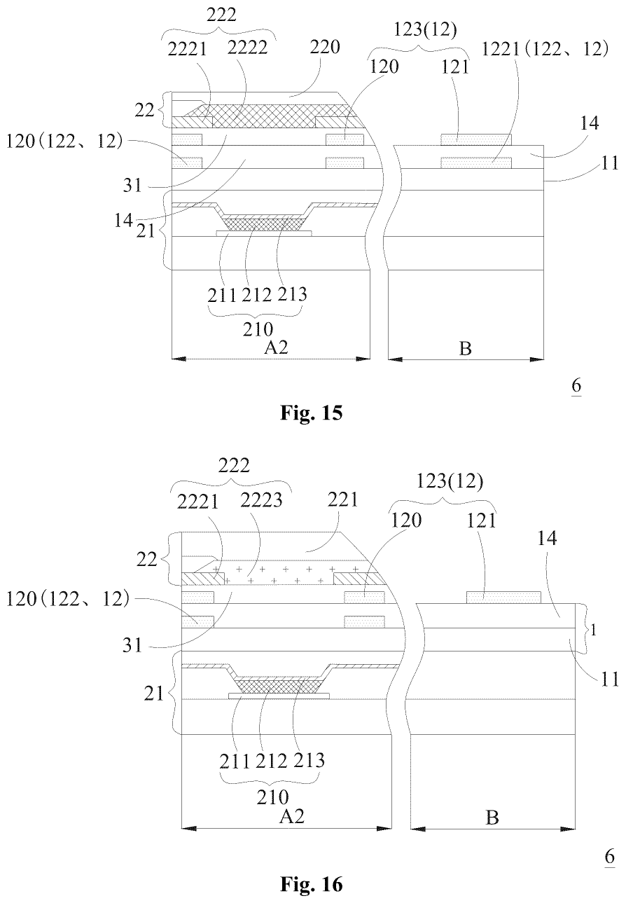

In another possible embodiment, as shown in FIG. 15, the second metal layer 123 comprises a bonding pad 121 located in the bonding area B; and the third organic layer 31 is located on a side of the second metal layer 123 away from the substrate 11.

In the above embodiment, the bonding pad 121 is located on the second metal layer 123, which may further form a metal wiring 120 located in the display area A2, and the third organic layer 31 is located on a side of the metal wiring 120 away from the substrate 11, so that the third organic layer 31 can protect and insulate the metal wiring 120.

In the above embodiment, the first metal layer 122 comprises a touch lead 1221 located in the bonding area B and electrically connected with the bonding pad 121.

In a possible embodiment, the bonding pad 121 comprises at least two metal layers stacked.

In the foregoing embodiment, the bonding pad 121 comprises a first titanium metal layer, an aluminum metal layer, and a second titanium metal layer that are stacked.

In an embodiment, the base plate is an array base plate, the metal layer 12 is an array metal layer, the third organic layer 31 is a planarization layer, and the specific structure of the base plate may refer to the previous embodiments, which will not be described in detail herein.

In an embodiment, as shown in FIG. 13 to FIG. 18, the optical improvement layer 22 comprises at least one of a color filter layer 222 and a microlens layer 223; the display module further comprises a display panel 21, light emitted by the display panel 21 is adjusted by the optical improvement layer 22, thereby achieving a better display effect.

In an embodiment, the display panel 21 comprises a light-emitting layer comprising a plurality of light-emitting units 210, and the optical improvement layer 22 comprises a color filter layer 222; the second organic layer 221 is located on a side of the color filter layer 222 away from the substrate 11 and protect the color filter layer 222.

In an embodiment, as shown in FIG. 13 to FIG. 15, the color filter layer 222 comprises a light shielding layer 2221 and color filter portions 2222, orthographic projections of the color filter portions 2222 on the substrate 11 at least partially overlap with orthographic projections of the light-emitting units 210 on the substrate 11, and the light shielding layer 2221 is located between the color filter portions 2222.

In the above embodiment, the color filter portion 2222 may correspond to the color of the light-emitting unit 210, and the color filter portion 2222 may filter the light emitted by the light-emitting unit 210 to improve the purity of the light emitted and reduce the incident rate of the external light entering the display panel 21, thereby reducing the reflectivity of the display panel 21 to the light incident into the display panel 21.

In the above embodiment, the light shielding layer 2221 can prevent crosstalk and absorb external light incident into the display module to reduce reflection. Specifically, the light shielding layer 2221 may be black and may comprise a black colorant, which may comprise black dyes or black pigments, such as carbon black and the like.

In another possible embodiment, as shown in FIG. 16, the color filter layer 222 comprises a light shielding layer 2221 and a reflection control layer 2223 selectively absorbs light of a specific wavelength band among light reflected from the inside of the display module or light incident from the outside of the display module. For example, the reflection control layer 2223 may absorb light in a first wavelength band of about 490 nm to about 505 nm and a second wavelength band of about 585 nm to about 600 nm, such that a transmittance of the light in the first wavelength band and the second wavelength band is reduced. The reflection control layer 2223 may absorb light of wavelengths outside wavelength ranges of red light, green light, and blue light respectively emitted from the light-emitting unit 210. Since the reflection control layer 2223 absorbs light of wavelengths not belonging to the wavelength range of the red light, the green light, and the blue light emitted from the display panel 21, the problem of brightness reduction of the display module can be improved. In addition, a reduction in light-emitting efficiency of the display module can be prevented or minimized, and visibility of the display module can be improved.

The reflection control layer 2223 may comprise an organic material layer comprising at least one of a dye and a pigment. The reflection control layer 2223 may comprise at least one of a tetraazaporphyrin (TAP) based compound, a porphyrin based compound, a metalloporphyrin based compound, an oxazinyl compound, a squartyl compound, a triarylmethane based compound, a polymethynyl compound, an anthraquinone based compound, a phthalocyanine based compound, an azo based compound, a perylene-based compound, a xanthene based compound, a diimine based compound, and a dipyrromethylene based compound, a cyaninyl compound.

In an embodiment, the reflection control layer 2223 may have a transmittance of about 64% to about 72%. The transmittance of the reflection control layer 2223 may be controlled according to the amount of pigment and/or dye comprised in the reflection control layer 2223.

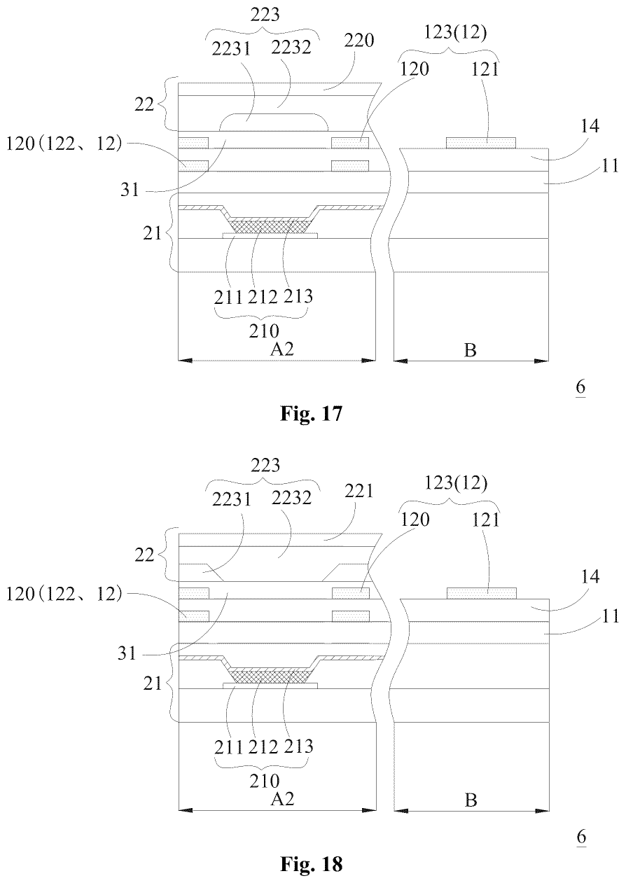

And/or, as shown in FIG. 17, the optical improvement layer 22 comprises a microlens layer 223 comprising a first optical functional layer 2231 and a second optical functional layer 2232 that are stacked, a refractive index of the first optical functional layer 2231 being different from that of the second optical functional layer 2232; the second organic layer 221 is located on a side of the microlens layer 223 away from the substrate 11.

In the foregoing embodiment, the second optical functional layer 2232 is located on a side of the first optical functional layer 2231 away from the display panel 21, a refractive index of the second optical functional layer 2232 being less than that of the first optical functional layer 2231. The first optical functional layer 2231 may comprise a plurality of pattern parts opposite to the light-emitting units 210, the pattern parts comprise middle parts and edge parts surrounding the middle parts, a thickness of the edge part tending to decrease along a direction from the middle part to the edge part; therefore, when light (oblique light emitted by the light-emitting unit 210) passes through the first optical functional layer 2231 with a higher refractive index and is incident into the second optical functional layer 2232, the oblique light is refracted, so that the oblique light is converted into light more toward a positive viewing angle, that is, the light is closer to a center of the light-emitting element, thereby achieving an effect of converging the light, and further improving display brightness of the display module.

In the above embodiment, as shown in FIG. 18, the refractive index of the second optical functional layer 2232 is greater than the refractive index of the first optical functional layer 2231, the first optical functional layer 2231 may comprise a plurality of pattern parts staggered with the light-emitting units 210, that is, the pattern parts are located between adjacent light-emitting units 210. The pattern parts comprise middle parts and edge parts surrounding the middle parts, a thickness of the edge part tends to decrease along the direction from the middle part to the edge part; therefore, when the light (the light emitted by the light-emitting unit 210 from the inclined light through the upper film layer) passes through the second optical functional layer 2232 with a higher refractive index and is incident into the first optical functional layer 2231 with a lower refractive index, the oblique light is refracted, so that the oblique light is converted into light more toward a positive viewing angle, that is, the light is closer to a center, thereby achieving an effect of converging the light, and further improving display brightness of the display module.

Specifically, the display module further comprises an encapsulation layer (not shown) located between the optical improvement layer 22 and the display panel 21. Specifically, the encapsulation layer is configured to encapsulate the display panel 21.

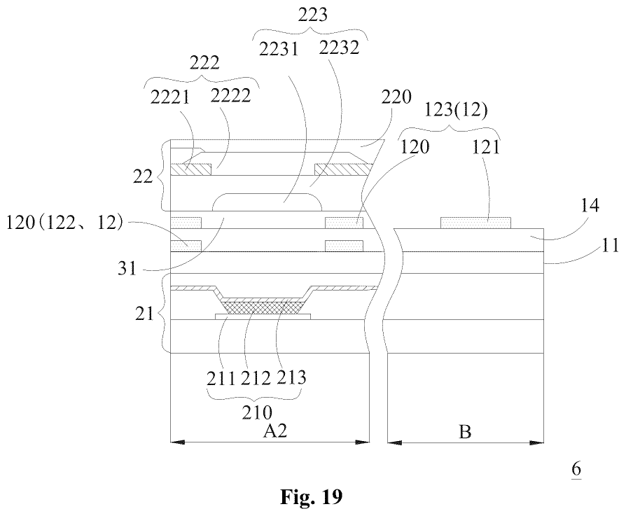

In an embodiment, as shown in FIG. 19, the optical improvement layer 22 comprises a color filter layer 222 and a microlens layer 223, where the color filter layer 222 is located on a side of the microlens layer 223 away from the display panel 21. The fourth organic layer 220 is located on a side of the optical improvement layer 22 away from the display panel 21 for protecting the optical improvement layer 22.

Specifically, the light shielding layer 2221 in the color filter layer 222 may also be located between the plurality of pattern parts of the first optical functional layer 2231 in the microlens layer 223, and the color filter part 2222/the reflection control layer 2223 is opposite to the pattern parts, which is not particularly limited in the present application.

In an embodiment, the third organic layer 31 and the fourth organic layer 220 comprise an organic adhesive; by the third organic layer 31 and the fourth organic layer 220 using an organic adhesive, manufacturing can be facilitated, and in the process of thinning the second organic layer 221 to form the fourth organic layer 220, a part of the first organic layer 13 located in the bonding area B can be removed to form the third organic layer 31, thereby simplifying the manufacturing process.

In the above embodiment, the third organic layer 31 and the second organic layer 221 comprise an acrylic adhesive layer, a silica gel layer, a polyurethane adhesive layer, an ultraviolet curing adhesive layer, a polyimide adhesive layer or a photoresist layer. The above organic adhesive material is easy to obtain and low in cost; other organic adhesives may also be used, which is not particularly limited in the present application.

In an embodiment, as shown in FIG. 19, no other film layer is provided in the same layer as the bonding pad 121 in the bonding area B of the display module 6. Since the third organic layer 31 and the fourth organic layer 220 comprise organic adhesive, specifically, the third organic layer 31 and the fourth organic layer 220 may be formed by ashing the first organic layer and the second organic layer, that is, in the process of thinning the second organic layer 221 to form the fourth organic layer 220, a part of the first organic layer 13 located in the bonding area B is removed to form the third organic layer 31, so that the manufacturing process can be simplified, meanwhile, a part of the first organic layer 13 located in the bonding area B is completely removed, so that the peripheral side of the bonding pad 121 in the same layer and the side away from the substrate 11 are not provided with any film layer, thereby well exposing the bonding pad 121 to facilitate subsequent electrical connection.

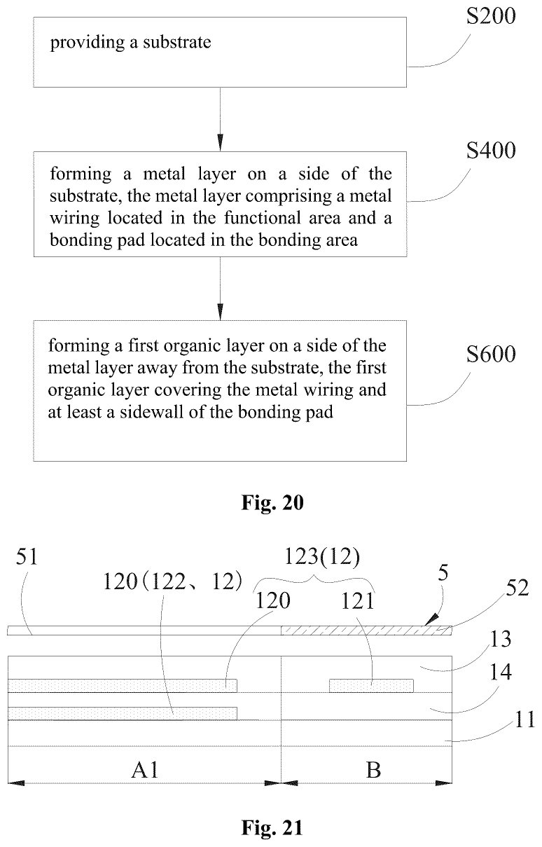

The present application further provides a method for manufacturing a base plate preform 1 comprising a bonding area B and a functional area A1, as shown in FIG. 20, the method comprises:

S200, providing a substrate 11.

S400, forming a metal layer 12 on a side of the substrate 11, the metal layer 12 comprising a metal wiring 120 located in the functional area A1 and a bonding pad 121 located in the bonding area B.

S600, forming a first organic layer 13 on a side of the metal layer away from the substrate 11, the first organic layer 13 covering the metal wiring 120 and at least a sidewall of the bonding pad 121.

In the above method, by forming the first organic layer 13 to protect the metal wiring 120 and the bonding pad 121 and further protect the material in the bonding pad 121, the damage to the bonding pad 121 caused by the subsequent process can be improved, the damage to the bonding pad 121 caused by the subsequent process specifically comprises the problem that the bonding pad 121 is error side etched due to the corrosion of the material in the bonding pad 121 by the etching solution in the subsequent process.

In step S600, a first organic layer 13 is formed on a side of the metal layer away from the substrate 11, and the first organic layer 13 covers the functional area A1 and the bonding area B; that is, the first organic layer 13 may further completely cover the bonding pad 121, thereby further improving the protection effect on the bonding pad 121.

In the above embodiment, the thickness of the first organic layer 13 located in the functional area A1 is greater than or equal to that of the first organic layer 13 located in the bonding area B, so that the first organic layer 13 protects the bonding pad 121 during the subsequent process. Furthermore, the part of the first organic layer 13 located in the bonding area B is set to be relatively thin so as to remove the part of the first organic layer 13 located in the bonding area B while thinning other film layers in the subsequent process, thereby reducing the process of removing the part of the first organic layer 13 located in the bonding area B, simplifying the process and reducing the cost.

In the above embodiment, the first organic layer 13 comprises an acrylic adhesive layer, a silica gel layer, a polyurethane adhesive layer, an ultraviolet curing adhesive layer, a polyimide adhesive layer or a photoresist layer; it is convenient to synchronously remove the part of the first organic layer 13 located in the bonding area B in the subsequent thinning process, and the above organic adhesive material is easy to obtain and low in cost; other organic adhesives may also be used, which is not particularly limited in the present application.

In the above embodiment, a specific method for setting a thickness of the first organic layer 13 located in the functional area A1 greater than that of the first organic layer 13 located in the bonding area B comprises:
S601, as shown in FIG. 21, providing a mask plate 5 on a side of the first organic layer 13 away from the display panel 21, the mask plate 5 comprising a non-light-transmitting area 51 corresponding to the functional area A1 and a semi-light-transmitting area 52 corresponding to the bonding area B;
S602, illuminating the first organic layer 13 on a side of the mask plate 5 away from the first organic layer 13;
S603, developing an area on the base plate preform 1 corresponding to the semi-light-transmitting area by a developing solution, so that the thickness of the first organic layer 13 located in the functional area A1 is greater than that of the first organic layer 13 located in the bonding area B.

Referring to FIG. 13, a part of the first organic layer 13 located in the bonding area B is thinned by exposure and development, so that the thickness of the first organic layer 13 located in the functional area A1 is greater than that of the first organic layer 13 located in the bonding area B.

Specifically, the first organic layer 13 is made of an organic adhesive, and may be thinned by an exposure and development process. The mask plate 5 is provided on a side of the first organic layer 13 away from the display panel 21, so as to expose only a part of its area. Specifically, the semi-light-transmitting area 52 in the mask plate 5 and the bonding area B may be opposite and exposed to facilitate subsequent thinning of the part of the first organic layer 13 located in the bonding area B.

Specifically, the semi-light-transmitting area 52 comprises a light-shielding film layer, a material of which may comprise chromium oxide, whereas a material of the non-light-transmitting area 51 comprises chromium.

Alternatively, as shown in FIG. 23, the semi-light-transmitting area 52 comprises a plurality of strip-shaped through holes 521 penetrating along a thickness direction of the mask, a distance between adjacent strip-shaped through holes 521 being 1 μm-2 μm, for example, 1 μm, 1.2 μm, 1.4 μm, 1.5 μm, 1.8 μm, 2 μm, etc. Specifically, the strip-shaped through hole 521 may be a rectangular strip-shaped through holes 521. Due to the slit diffraction effect, the exposure light intensity in the slit is weakened, the part of the first organic layer 13 located in the bonding area B is opposite to the semi-light-transmitting area 52 and is partially exposed, since the strip-shaped through holes 521 are small, the exposure energy is weak, thus the exposed depth of the first organic layer 13 is different, after subsequently developing by the developing solution, the exposed part of the first organic layer 13 is removed, so that the height of the first organic layer 13 is reduced. The mask plate 5 of this embodiment is low in cost and the manufacturing cost of the display module can be reduced.

In another embodiment, the thickness of the part of the first organic layer 13 located in the functional area A1 is equal to that of the part of the first organic layer 13 located in the bonding area B, thereby simplifying the manufacturing process of the first organic layer 13.

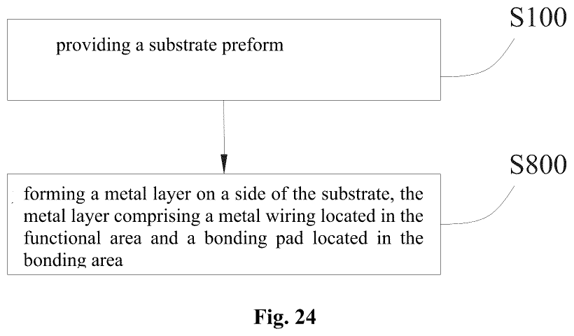

The present application further provides a method for manufacturing a display module, as shown in FIG. 24, comprising:

S100, providing a base plate preform 1;
the base plate preform 1 being the base plate preform 1 in any one of the above embodiments, or the base plate preform 1 manufactured by the method of any one of the above base plate preforms 1;
forming the base plate preform 1, specifically comprising: S200, providing a substrate 11; S400, forming a metal layer 12 on a side of the substrate 11, the metal layer 12 comprising a metal wiring 120 located in the functional area A1 and a bonding pad 121 located in the bonding area B; S600, forming a first organic layer 13 on a side of the metal layer away from the substrate 11, the first organic layer 13 covering the metal wiring 120 and at least a sidewall of the bonding pad 121;
S800, forming an optical improvement layer 22 on a side of the first organic layer 13 away from the substrate 11.

In the above method, by forming the first organic layer 13 to protect the metal wiring 120 and the bonding pad 121, the material in the bonding pad 121 can be protected, the damage to the bonding pad 121 caused by the subsequent process can be improved, the damage to the bonding pad 121 caused by the subsequent process specifically comprises the problem that the bonding pad 121 is error side etched due to the corrosion of the material in the bonding pad 121 by the etching solution in the subsequent process. Further, the first organic layer 13 may further completely cover the bonding pad 121, thereby further improving the protection effect on the bonding pad 121.

In step S800, the step of forming the optical improvement layer 22 on the side of the first organic layer 13 away from the substrate 11 comprises:
S801, forming a second organic layer 221 on a side of the first organic layer 13 away from the substrate 11, an orthographic projection of the second organic layer 221 on the substrate 11 not overlapping with an orthographic projection of the bonding pad 121 on the substrate 11, wherein the second organic layer 221 is used to protect the optical improvement layer 22 located in the functional area A1, the second organic layer 221 is located in the display area A2 to avoid shielding the bonding pad 121 in the bonding area B;
S802, thinning the first organic layer 13 located in the bonding area B and the second organic layer 221 to thin the second organic layer 221 and form a fourth organic layer 220, and removing a part of the first organic layer 13 located in the bonding area B to form a third organic layer 31, so that the third organic layer 31 covers the functional area A1.

Specifically, the second organic layer 221 and the first organic layer 13 may be made of the same material, so that they may be manufactured by the same manufacturing process, thereby reducing the manufacturing process type of the display module and simplifying the process.

In the above embodiment, the second organic layer 221 and the first organic layer 13 may be synchronously thinned by an ashing process, so that a process of removing a part of the first organic layer 13 located in the bonding area B to expose the bonding pad 121 may be reduced, thereby simplifying the process; meanwhile, due to the ashing process, the surface roughness of a side of the fourth organic layer 220 formed away from the substrate 11 may be further increased, so that the reflectivity of the fourth organic layer 220 is lower than that of the second organic layer 221, thereby improving the visual effect of the display module.

Specifically, in the above embodiment, the thickness of the first organic layer 13 located in the functional area A1 is greater than or equal to that of the first organic layer 13 located in the bonding area B, that is, the thickness of the part of the first organic layer 13 located in the bonding area B is relatively thin, in the synchronous ashing process of the part of the first organic layer 13 located in the bonding area B and the second organic layer 221, the part of the first organic layer 13 located in the bonding area B can be effectively removed and the bonding pad 121 is exposed, while the second organic layer 221 is not excessively thinned to lose the protection effect. In case that the thickness of the first organic layer 13 located in the functional area A1 is equal to the thickness of the first organic layer 13 located in the bonding area B, the thickness of the second organic layer 221 may be increased to prevent the second organic layer 221 from being excessively thinned to lose the protection effect when the part of the first organic layer 13 located in the bonding area B is removed and the pad is exposed.

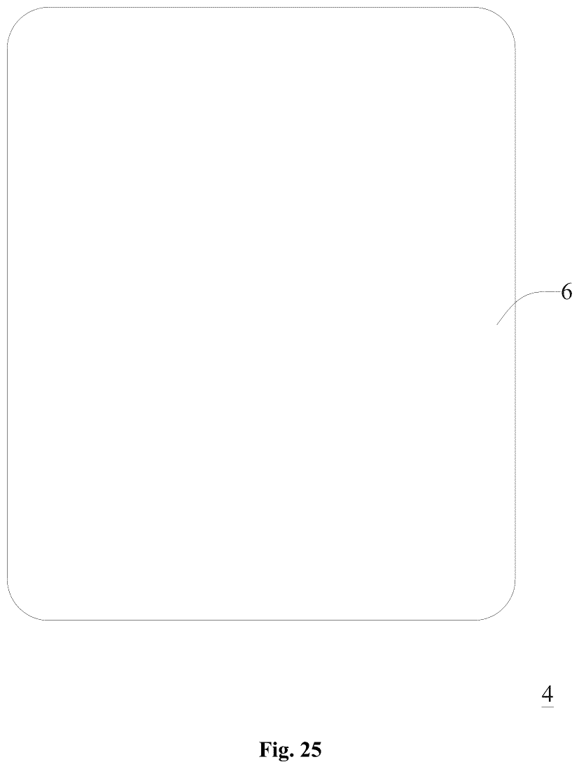

The present application further provides a display device 4, as shown in FIG. 25, comprising the display module 6 provided in the above embodiments of the present application; or, comprising the display module 6 manufactured by the method provided in the above embodiments of the present application.

Since the display device 4 provided by the present application comprises the display module 6 provided by the above embodiments, or comprises the display module 6 manufactured by the method provided by the above embodiments of the present application. Therefore, the display device 4 provided by the present application has the beneficial effects of any one of the display modules 6 provided by the above embodiments, and details are not described herein again.

The display device 4 in embodiments of the present application comprises, but is not limited to, a mobile phone, a personal digital assistant (PDA), a tablet computer, an electronic book, a television, an access control, a smartphone, a console, and other devices having a display function.

According to the above embodiments of the present application, the embodiments do not describe all details in detail, and do not limit the present application to these specific embodiments. Obviously, many modifications and variations can be made according to the above description. These embodiments are selected and specifically described in this specification to better explain the principles and practical applications of the present application, so that the skilled in the art can well use the present application and modify based on the present application. This application is limited only by the claims and their full scope and equivalents.

What is claimed is:

1. A base plate preform, comprising a functional area and a bonding area, the base plate preform further comprising:
a substrate;
a metal layer located on a side of the substrate, the metal layer comprising a metal wiring located in the functional area and a bonding pad located in the bonding area;
a first organic layer located on a side of the metal layer away from the substrate, the first organic layer covering the metal wiring and at least a sidewall of the bonding pad.

2. The base plate preform of claim 1, wherein the first organic layer covers the metal wiring and the bonding pad.

3. The base plate preform of claim 1, wherein the first organic layer covers the functional area and the bonding area;
a thickness of the first organic layer in the functional area is greater than or equal to a thickness of the first organic layer in the bonding area.

4. The base plate preform of claim 1, wherein the metal layer is a touch metal layer comprising a first metal layer, and the first organic layer is provided on a side of the first metal layer away from the substrate;
the touch metal layer further comprises a second metal layer located on a side of the first metal layer away from the substrate;
the first metal layer or the second metal layer comprising the bonding pad located in the bonding area;
the first organic layer is located between the first metal layer and the second metal layer, or the first organic layer is located on a side of the second metal layer away from the substrate.

5. The base plate preform of claim 4, wherein the first metal layer comprises a touch lead located in the bonding area, the touch lead being electrically connected with the bonding pad;
the metal layer is an array metal layer, and the first organic layer is a planarization layer.

6. A display module preform, comprising the base plate preform of claim 1.

7. The display module preform of claim 6, further comprising an optical improvement layer located on a side of the first organic layer away from the substrate;
the optical improvement layer comprises a second organic layer, an orthographic projection of the second organic layer on the substrate not overlapping with an orthographic projection of the bonding pad on the substrate.

8. The display module preform of claim 7, wherein the second organic layer covers the functional area;
the second organic layer comprises an organic adhesive; and
the second organic layer is made of a same material as the first organic layer.

9. The display module preform of claim 7, wherein the display module preform further comprises a light-emitting layer comprising a plurality of light-emitting units, and the optical improvement layer comprises at least one of a color filter layer or a microlens layer, the second organic layer being located on a side of the color filter layer away from the substrate, the color filter layer comprising a light shielding layer and color filter portions, orthographic projections of the color filter portions on the substrate at least partially overlapping with orthographic projections of the light-emitting units on the substrate, and the light shielding layer being located between the color filter portions.

10. The display module preform of claim 7, wherein the optical improvement layer comprises a microlens layer comprising a first optical functional layer and a second optical functional layer that are stacked, a refractive index of the first optical functional layer being different from a refractive index of the second optical functional layer, and the second organic layer being located on a side of the microlens layer away from the substrate.

11. A display module, comprising a display area and a bonding area, the display module further comprising a base plate comprising a substrate, a metal layer and a third organic layer, the metal layer being provided with a bonding pad in the bonding area, the third organic layer covering the display area, and an orthographic projection of the third organic layer on the substrate not overlapping with an orthographic projection of the bonding pad on the substrate.

12. The display module of claim 11, wherein the base plate is a touch base plate, the metal layer is a touch metal layer comprising a first metal layer, the third organic layer being provided on a side of the first metal layer away from the substrate.

13. The display module of claim 12, the touch metal layer further comprises a second metal layer located on a side of the first metal layer away from the substrate, the first metal layer or the second metal layer comprising the bonding pad located in the bonding area; and
the third organic layer is located between the first metal layer and the second metal layer, or the third organic layer is located on a side of the second metal layer away from the substrate.

14. The display module of claim 13, wherein the first metal layer comprises a touch lead located in the bonding area and electrically connected with the bonding pad;
the base plate is an array base plate, the metal layer is an array metal layer, and the third organic layer is a planarization layer;
the bonding pad comprises at least two metal layers stacked; and
the bonding pad comprises a first titanium metal layer, an aluminum metal layer and a second titanium metal layer that are stacked.

15. A method for manufacturing a base plate preform, the base plate preform comprising a bonding area and a functional area, the method comprising:
providing a substrate;
forming a metal layer on a side of the substrate, the metal layer comprising a metal wiring located in the functional area and a bonding pad located in the bonding area;
forming a first organic layer on a side of the metal layer away from the substrate, the first organic layer covering the metal wiring and at least a sidewall of the bonding pad.

16. The method of claim 15, wherein the first organic layer is formed on a side of the metal layer away from the substrate, and the first organic layer covers the functional area and the bonding area,
the step of forming a first organic layer on a side of the metal layer away from the substrate, the first organic layer covering the functional area and the bonding area comprises:
forming the first organic layer with a thickness in the functional area greater than or equal to a thickness in the bonding area.

17. The method of claim 16, wherein forming the first organic layer with a thickness in the functional area greater than or equal to a thickness in the bonding area comprises:
providing a mask plate on a side of the first organic layer away from the substrate, the mask comprising a non-light-transmitting area and a semi-light-transmitting area, the non-light-transmitting area being provided corresponding to the functional area, and the semi-light-transmitting area being provided corresponding to the bonding area;
illuminating a side of the mask plate away from the first organic layer;
developing an area of the semi-light-transmitting area corresponding to the base plate by a developing solution, to make a thickness of the first organic layer located in the functional area is greater than a thickness of the first organic layer located in the bonding area.

18. A method for manufacturing a display module, comprising:
providing a base plate preform manufactured by the method of claim 15,
the method further comprising forming an optical improvement layer on a side of the first organic layer away from the substrate, the optical improvement layer comprising a second organic layer formed on a side of the first organic layer away from the substrate, and an orthographic projection of the second organic layer on the substrate not overlapping with an orthographic projection of the bonding pad on the substrate;
thinning the first organic layer located in the bonding area and the second organic layer, to thin the second organic layer and form a fourth organic layer, and to remove a part of the first organic layer located in the bonding area to form a third organic layer, to make the third organic layer cover the functional area.

19. The method of claim 18, wherein the step of forming the second organic layer on a side of the first organic layer away from the substrate comprises: covering the functional area with the second organic layer;
the step of thinning the first organic layer located in the bonding area and the second organic layer comprises: ashing the first organic layer located in the bonding area and the second organic layer.
